(19) United States
(12) Patent Application Publication
(10) Pub. No.: US 2024/0030050 A1
(43) Pub. Date: Jan. 25, 2024

(54) APPARATUS FOR PROCESSING WAFER-SHAPED ARTICLES

(71) Applicant: LAM RESEARCH AG, Villach (AT)

(72) Inventors: Alois GOLLER, Villach (AT); Roman FUCHS, Villach (AT)

(21) Appl. No.: 18/028,957

(22) PCT Filed: Sep. 29, 2021
(86) PCT No.: PCT/EP2021/076836

§ 371 Date: Mar. 28, 2023

(30) Foreign Application Priority Data
Sep. 30, 2020 (GB) 2015527.1

(51) Int. Cl. H01L 21/67; H01L 21/324; H05B 3/00

(52) U.S. Cl. CPC H01L 21/67115; H01L 21/324; H05B 3/0047

(57) ABSTRACT

Apparatus for processing wafer-shaped articles, the apparatus comprising: a support configured to support a wafer-shaped article; a heating assembly comprising an array of light-emitting heating elements configured to heat a wafer-shaped article supported by the support; and a gas supply mechanism configured to supply to the array of light-emitting heating elements: a first gas having an oxygen content of less than 1% by volume; and a second gas having an oxygen content that is at least 2% by volume higher than the first gas.

### FIELD OF THE INVENTION

The present invention relates to apparatus for processing wafer-shaped articles. The present invention also relates to a method of limiting degradation of light-emitting heating elements, or at least partially restoring the output of light-emitting heating elements, in apparatus for processing wafer-shaped articles.

### BACKGROUND OF THE INVENTION

Semiconductor wafers may be subjected to various surface treatment processes, such as etching, cleaning, polishing and material deposition. To perform such processes, a wafer may be mounted on a rotatable chuck, so that various processes can be performed on a surface of the wafer.

For example, the surface of the wafer may be cleaned by applying a cleaning liquid or rinse liquid such as isopropyl alcohol or de-ionised water to the surface of the wafer. The surface of the wafer may then be dried by spinning the wafer using the rotatable chuck and heating the wafer to cause evaporation of the cleaning liquid or rinse liquid. Such a cleaning process is commonly referred to as a spin-clean process.

An example of an apparatus that may be used for cleaning the surface of a wafer is described in US2017/0345681A1, the contents of which are incorporated herein by reference.

The apparatus described in in US2017/0345681A1 includes a rotatable chuck on which a wafer is mountable, and a liquid dispenser for dispensing liquid on an upper surface of the wafer when the wafer is mounted on the rotatable chuck. The apparatus also includes an array of LED heating elements disposed below the wafer when the wafer is mounted in the rotatable chuck, and arranged to heat the wafer. After liquid is dispensed on the surface of the wafer, the array of LED heating elements is controlled to heat the wafer to cause evaporation of the liquid.

During processing of a wafer, one or more flammable liquids may be dispensed on to a surface of the wafer. For example, as mentioned above, isopropyl alcohol may be dispensed on to an upper surface of a wafer in order to clean the upper surface of the wafer in a spin-clean process.

With such flammable liquids, there is potentially a risk of fire or explosion when the array of LED heating elements is controlled to heat the wafer to cause evaporation of the liquid. In particular, an electrical circuit is provided for supplying electrical power to the array of LED heating elements. If the flammable liquid comes into contact with the electrical circuit, there is a risk that the electrical circuit may cause the flammable liquid to catch fire or to explode.

In order to reduce the risk of such fire or explosion, it is known to operate the array of LED heating elements in an inert atmosphere, for example an atmosphere of pure nitrogen. This is achieved by providing a gas supply mechanism that provides a supply of inert gas to the array of LED heating elements. The lack of oxygen in the inert atmosphere means that even if the flammable liquid comes into contact with the electrical circuit, a fire or explosion can be prevented.

### SUMMARY OF THE INVENTION

The present inventors have discovered that, surprisingly, operating the LEDs of the array of LED heating elements in an inert atmosphere causes degradation in the light output of the LEDs over time. For example, the light output of the LEDs has been found to fall to as low as 30% of the original light output of the LEDs after prolonged operation in an inert atmosphere. It has also been observed by the present inventors that significant decolouration of the LEDs occurs after prolonged operation in the inert atmosphere.

The exact process by which the degradation in the light output of the LEDs occurs is not presently fully understood, but is not considered to be essential to the present invention. However, without wishing to be bound by any particular theory, it is believed that the degradation in the light output of the LEDs occurs as a consequence of the LEDs being operated in an inert atmosphere that does not contain oxygen (or contains only a small amount of oxygen).

For example, the present inventors have observed that operating the LEDs in a normal atmosphere (for example air) causes a drop of less than 10% of the light output of the LEDs over the whole operational lifetime of the LEDs. Therefore, the same degradation in the light output of the LEDs does not occur in air, which contains a significant volume of oxygen.

The present inventors have further discovered that, surprisingly, this degradation in the light output of the LEDs can be substantially reversed by providing the LEDs with a normal atmosphere (for example air) while operating the LEDs.

Again, the exact process by which the degradation in the light output of the LEDs is reversed is not presently fully understood, but is not considered to be essential to the present invention. However, without wishing to be bound by any particular theory, it is believed that the reversal of the degradation in the light output of the LEDs occurs as a consequence of the LEDs being operated in an atmosphere that contains oxygen, instead of an inert atmosphere.

Therefore, at its most general, the present invention relates to improving the output of light-emitting heating elements that have been degraded by being operated in an inert atmosphere (e.g. an atmosphere with no oxygen or very low oxygen, e.g. less than 1% oxygen by volume) by providing the light-emitting heating elements with an atmosphere containing more oxygen than the inert atmosphere.

In particular, the degradation in the output of the light-emitting heating elements can be at least partially repaired by providing the light-emitting heating elements with an atmosphere containing more oxygen. In practice, the light-emitting heating elements are also operated at the same time as being provided with the atmosphere containing more oxygen to speed up the repair of the degradation.

According to a first aspect of the present invention there is provided an apparatus for processing wafer-shaped articles, the apparatus comprising:
a support configured to support a wafer-shaped article;
a heating assembly comprising an array of light-emitting heating elements configured to heat a wafer-shaped article supported by the support; and
a gas supply mechanism configured to supply to the array of light-emitting heating elements:
   a first gas having an oxygen content of less than 1% by volume; and
   a second gas having an oxygen content that is at least 2% by volume higher than the first gas.

Therefore, with the present invention, the gas supply mechanism can supply a first gas having an oxygen content of less than 1% by volume (an inert gas) to the light-emitting heating elements when processing a wafer-shaped article, to reduce the risk of fire or explosion when processing a wafer-shaped article. In addition, the gas supply mechanism can supply a second gas having a greater oxygen content to the light-emitting heating elements to at least partially restore the light output of the degraded light-emitting heating elements.

Therefore, with the present invention, the light output of the light-emitting heating elements can be at least partially restored by supplying the second gas to the light-emitting heating elements.

The apparatus according to the first aspect of the present invention may have any one, or, where compatible, any combination of the following optional features.

The gas supply mechanism may be configured to alternatively supply to the array of light-emitting heating elements the first gas and the second gas. In other words, the gas supply mechanism may be configured to supply the first gas and not the second gas, or the second gas and not the first gas, at any given time.

The gas supply mechanism may be configured to alternatively supply gas with at least two different oxygen contents to the array of light-emitting heating elements.

The support may be a wafer holder that is adapted to hold a wafer.

The support may be a chuck.

The support may be rotatable. For example, the support may be a rotatable chuck.

The support may be configured to rotate the wafer relative to an axis of rotation of the support that is substantially perpendicular to a surface of the wafer.

The support may include a mechanism adapted to receive the wafer and hold the wafer securely in place relative to the support (e.g. a clamp, screw, vacuum holder, plurality of gripping pins, etc.).

The support may be adapted to receive a wafer of a predetermined size, e.g. a wafer having a diameter of 300 mm or 450 mm.

The support may include a motor for driving rotation of the support relative to the axis of rotation. Alternatively, the support may be caused to rotate by an external driving means, for example via magnetic induction.

The wafer-shaped article may be a wafer, for example a semiconductor wafer.

The heating assembly serves to heat a wafer supported by the support. The heating assembly comprises an array of light-emitting heating elements arranged to illuminate a wafer supported by the support.

The light-emitting heating elements heat the wafer by radiative heating using light.

The term “array” may merely mean a plurality of light-emitting heating elements, and does not necessarily mean that the light-emitting heating elements are arranged in any particular order.

The array of light-emitting heating elements may be arranged to face towards the wafer when the wafer is received by the support.

The array of light-emitting heating elements may be arranged to face towards a first surface of the wafer, which is opposite a second surface of the wafer on which processing (e.g. cleaning, deposition of material, etc.) is performed.

The light-emitting heating elements may be disposed on a substantially plane surface (e.g. on a board, such as a circuit board).

The board may be arranged to be substantially parallel to the wafer when the wafer is received by the rotatable chuck.

The light-emitting heating elements may be substantially uniformly distributed over the plane surface, to illuminate the wafer in a uniform manner, which may result in uniform heating of the wafer.

The array of light-emitting heating elements may be arranged to cover an area that is substantially the same as an area of the wafer, or an area that is within 10% of an area of the wafer.

All of the light-emitting heating elements may be of the same type (e.g. they may all have the same characteristics).

In general, a light-emitting heating element is an element (or part) that performs radiative heating using light.

The light emitted by the light-emitting heating element may be visible light.

Where the support is rotatable, the heating assembly may be mounted relative to the support such that it does not rotate together with the support when the support is rotated about the axis of rotation. In other words, the array of light-emitting heating elements may remain stationary when the support is rotated about the axis of rotation. This may facilitate providing electrical connections to the array of light-emitting heating elements.

Herein, a light-emitting heating element may refer to a light source which emits light at a wavelength suitable for heating a wafer. For example, a light-emitting heating element may emit light having a maximum intensity in a wavelength range from 380 nm to 650 nm.

In some embodiments, the light-emitting heating elements may comprise phosphor.

In some embodiments, one or more of the light-emitting heating elements may be light emitting diodes (LEDs). All of the light-emitting heating elements may be LEDs.

The light-emitting heating elements may be arranged in the heating assembly on concentric circles (concentric about a centre of the heating assembly).

In each concentric circle the heating elements may be bunched into different groups. In other words, the heating elements in a respective concentric circle may not be evenly distributed around that concentric circle.

Each of the different groups may contain the same number of heating elements, for example 16 heating elements.

The different groups of light-emitting heating elements may be independently controlled, for example by different power being supplied to different groups of the light-emitting heating elements, and/or by different groups of the light-emitting heating elements being operated at different times.

The gas supply mechanism is configured to supply to the array of light-emitting heating elements:
a first gas having an oxygen content of less than 1% by volume; and
a second gas having an oxygen content that is at least 2% by volume higher than the first gas.

The gas supply mechanism may be configured to only provide one of the first and second gases to the array of light emitting heating elements at a time. In other words, the gas supply mechanism may provide either the first gas or the second gas to the array of light-emitting heating elements at a time, not both at the same time.

A gas supply mechanism means any arrangement for supplying gas to the array of light emitting heating elements, and may include for example one or more valves and one or more gas flow passages such as a pipe or tube.

The gas supply mechanism may comprise a first container containing the first gas and a second container containing the second gas.

The gas supply mechanism may comprise a first gas pipe connected to a first source containing the first gas and a second gas pipe connected to a second source containing the second gas.

Supplying a gas to the array of light-emitting heating elements means providing the gas around the light-emitting heating elements, and/or to the outsides of the light-emitting heating elements.

For example, the array of light emitting heating elements may be contained in a chamber, volume, or space, and supplying the gas to the array of light emitting heating elements may comprise supplying the gas to the chamber, volume, or space containing the array of light emitting heating elements.

The first gas may have an oxygen content of less than by volume, or less than 0.1% by volume.

The first gas may be an inert gas. Inert may mean that the gas is inert with respect to the processing liquid used in the processing of the wafer-shaped article. For example, the gas may be inert with respect to isopropyl alcohol.

The oxygen content of the first gas may be insufficient for combustion. For example, the oxygen content of the first gas may be insufficient for combustion of isopropyl alcohol.

The first gas may comprise nitrogen or may be nitrogen, for example pure nitrogen, or any noble gas, e.g. argon.

The first gas may comprise carbon dioxide or be carbon dioxide.

Alternatively, the first gas may have an oxygen content of less than 2% by volume.

The first gas is a gas not reacting with flammable substances.

The second gas may have an oxygen content that is at least 5% by volume higher than the first gas.

The oxygen content of the second gas may be more than 2% by volume, or more than 3% by volume, or more than 4% by volume, or more than 5% by volume. The second gas may have an oxygen content of more than 10% by volume, or more than 15% by volume.

The second gas may comprise air or be air, for example extra clean dry air.

The second gas may be a mixture of air and one or more other gases, for example a mixture of air and an inert gas or noble gas, for example nitrogen.

The apparatus may be configured to produce the first gas or the second gas by mixing together one or more gases supplied by one or more gas supplies.

Supplying the first gas to the array of light-emitting elements may mean that only the first gas is supplied to the array of light-emitting elements.

Supplying the second gas to the array of light-emitting elements may mean that only the second gas is supplied to the array of light-emitting elements.

In practice, the apparatus is configured to supply the first gas to the array of light-emitting heating elements during processing of a wafer-shaped article by the apparatus. For example, processing of the wafer-shaped article may comprise dispensing a liquid such as isopropyl alcohol onto a surface of the wafer-shaped article and heating the wafer-shaped article, and the first gas may be supplied to the array of light-emitting heating elements at the same time as dispensing a liquid such as isopropyl alcohol onto the surface of the wafer-shaped article and/or heating the wafer-shaped article. The process sequences may be programmed into a controller.

The first gas preferably provides an inert atmosphere around the array of light-emitting heating elements during the processing of the wafer-shaped article.

In practice, the apparatus is configured to only supply the second gas to the array of light-emitting heating elements when a wafer-shaped article is not being processed by the apparatus. In particular, since the second gas contains more oxygen, there is a greater risk of fire or explosion when flammable processing liquids are used during processing of the wafer-shaped article. Therefore, it is preferable for the second gas not to be supplied to the array of light-emitting heating elements when a wafer-shaped article is being processed, for safety.

The apparatus may comprise a liquid dispenser for dispensing a liquid on to a surface of the wafer-shaped article. For example, the liquid dispenser may comprise a rotatable dispensing arm having a dispensing nozzle. The liquid may be a flammable liquid, such as isopropyl alcohol.

In practice, the apparatus is configured to only supply the second gas to the array of light-emitting heating elements when the flammable liquid is not being dispensed on to the surface of the wafer-shaped article. A controller may be provided to control operation of the apparatus so that the second gas (oxygen-containing gas) is only supplied when the flammable liquid is not being dispensed on to the surface of the wafer-shaped article. In particular, since the second gas contains more oxygen, there is a greater risk of fire or explosion when flammable processing liquids are used during processing of the wafer-shaped article.

The array of light-emitting heating elements may be arranged to heat a surface of the wafer that is on an opposite side of the wafer compared to the surface of the wafer on which the liquid is dispensed.

The apparatus may be configured to provide power to the array of light-emitting heating elements while the second gas is being supplied to the array of light-emitting heating elements.

As mentioned above, providing power to the array of light-emitting heating elements while there are in an atmosphere of the second gas significantly speeds up the restoration of the output of the light-emitting heating elements.

The same power may be provided to each of the light-emitting heating elements. Alternatively, different power may be provided to different light-emitting heating elements, or to different groups of the light-emitting heating elements. The power provided to the light-emitting heating elements may be less than the power provided to the light emitting heating elements when processing a wafer-shaped article.

The apparatus may alternate providing power to the light-emitting heating elements and not providing power to the light-emitting heating elements while the second gas is supplied to the array of light-emitting heating elements.

The apparatus may be configured to only provide the second gas to the array of light-emitting heating elements when no wafer-shaped article is supported by the support.

The apparatus may be configured to:
supply the second gas to the array of light-emitting heating elements after a predetermined period of time of processing of wafer-shaped articles by the apparatus has elapsed; and/or
supply the second gas to the array of light-emitting heating elements after a predetermined number of wafer-shaped articles have been processed by the apparatus; and/or
supply the second gas to the array of light-emitting heating elements when an output of one or more of the light-emitting heating elements has dropped by a predetermined amount, or is a predetermined value; and/or
supply the second gas to the array of light-emitting heating elements based on a predetermined schedule.

Alternatively, the apparatus may be configured to supply the second gas to the light-emitting heating elements after each time a wafer-shaped article is processed by the apparatus. This may prevent significant degradation of the light-emitting heating elements from occurring in the first place.

Alternatively, the apparatus may be configured to supply the second gas to the light-emitting heating elements after each time the first gas is supplied to the light-emitting heating elements. This may prevent significant degradation of the light-emitting heating elements from occurring in the first place.

The gas supply mechanism may comprise a first gas path (or gas line) connected to a source of the first gas, and a second gas path (or gas line) connected to a source of the second gas.

The gas supply mechanism may comprise one or more valves configured to control the supply of the first gas and/or the supply of the second gas to the array of light-emitting heating elements. The one or more valves may control the supply of both the first and second gasses, or the supply of only the second gas.

The gas supply mechanism may comprise:
a first valve for connecting to a source of the first gas, and a gas flow path for transporting the first gas from the first valve to the array of light-emitting heating elements; and
a second valve for connecting to a source of the second gas, and a gas flow path for transporting the second gas from the second valve to the array of light-emitting heating elements.

Alternatively, the gas supply mechanism may comprise a multi-way valve connected to a source of the first gas and a source of the second gas, and a gas flow path for transporting the first gas and the second gas from the multi-way valve to the array of light-emitting heating elements. For example, the multi-way valve may be a three-way valve. The multi-way valve may be operable to supply the first gas and also operable to supply the second gas, for example by switching from the first gas to the second gas. Therefore, the supply of the first and second gases may be controlled using a single valve, instead of the first and second valves.

Alternatively, the gas supply mechanism may comprise a first gas path connected to a source of the first gas, a second gas path connected to a source of the second gas, and a valve in the second gas path. Therefore, the valve can be closed so that only the first gas is supplied, or opened so that a mixture of the first and second gases is supplied. The mixture of the first and second gases may be controlled so that the resulting gas has an oxygen content that is at least 2% by volume more than the oxygen content of the first gas alone. Therefore, only a single valve in the second gas path may be provided, instead of the first and second valves.

The gas supply mechanism may also comprise a container of the first gas connected to the first valve. The gas supply mechanism may also comprise a container of the second gas connected to the second valve.

The one or more valves may be electronic valves that are controlled by a controller of the apparatus. For example, during processing of a wafer the controller may control the first valve to be open and the second valve to be closed. In contrast, when restoring the output of the light-emitting heating elements the controller may control the first valve to be closed and the second valve to be open.

The gas flow path for transporting the first gas from the first valve to the array of light-emitting heating elements and the gas flow path for transporting the second gas from the second valve to the array of light-emitting heating elements may be combined along part of their extents. For example, these flow paths may be combined as a single flow path upstream of the light-emitting heating elements. For example, they may be combined as a single flow path in the stationary post 25.

According to a second aspect of the present invention, there is provided an apparatus for processing wafer-shaped articles, the apparatus comprising:
a support configured to support a wafer-shaped article;
a heating assembly comprising an array of light-emitting heating elements configured to heat a wafer-shaped article supported by the support; and
a gas supply mechanism configured to supply gas to the array of light-emitting heating elements, wherein the gas supply mechanism comprises:
a first gas path connected to a source of the first gas;
a second gas path connected to a source of the second gas; and
one or more valves configured to control the supply of the first gas and/or the supply of the second gas to the array of light-emitting heating elements.

The second aspect of the present invention may comprise any of the features of the first aspect of the present invention discussed above, where compatible.

In particular, the first gas and the second gas may have any of the features of the first and second gases discussed above.

In addition, the support, heating assembly and gas supply mechanism may have any of the features of the support, heating assembly and gas supply mechanism discussed above.

The gas supply mechanism may comprise:
a first valve for connecting to a supply of a first gas, and a gas flow path for transporting the first gas from the first valve to the array of light-emitting heating elements; and
a second valve for connecting to a supply of a second gas, and a gas flow path for transporting the second gas from the second valve to the array of light-emitting heating elements.

In the first aspect of the present invention, degradation of the light-emitting heating elements occurs due to operation of the light-emitting heating elements in an atmosphere containing no oxygen, or very little oxygen. The degradation is then at least partially repaired by providing the light-emitting heating elements with an atmosphere containing more oxygen.

In a third aspect of the present invention, a gas is provided to the light-emitting heating elements during processing of the wafer-shaped article that has an oxygen content that is sufficiently high to prevent significant degradation of the light-emitting heating elements during operation of the light-emitting heating elements in an atmosphere of the gas, but that is sufficiently low to reduce a risk of fire or explosion of flammable processing liquids. In this case, degradation of the light-emitting heating elements may be limited, and therefore restoration of the output of the light-emitting heating elements may not be required.

Therefore, according to the third aspect of the present invention there is provided an apparatus for processing wafer-shaped articles, the apparatus comprising:
a support configured to support a wafer-shaped article;
a heating assembly comprising an array of light-emitting heating elements configured to heat a wafer-shaped article supported by the support; and
a gas supply mechanism configured to supply to the array of light-emitting heating elements a gas having an oxygen content of greater than 1% by volume during processing of a wafer-shaped article by the apparatus.

The third aspect of the present invention may comprise any of the features of the first or second embodiment described above, where compatible.

The gas may have an oxygen content of more than 2% by volume, or more than 3% by volume, or more than 4% by volume, or more than 5% by volume.

The gas may have an oxygen content of less than 10% by volume, or less than 9% by volume, or less than 8% by volume, or less than 7% by volume, or less than 6% by volume.

The oxygen content of the gas may be insufficient for combustion, for example insufficient for combustion of isopropyl alcohol.

Supplying the gas to light-emitting heating elements during processing of the wafer-shaped article by the apparatus may mean supplying the gas to the light-emitting heating elements while a wafer is supported by the support and/or while a processing liquid is dispensed onto the wafer-shaped article.

The support and heating assembly may have any of the features of the support and heating assembly of the first aspect of the invention discussed above.

The gas supply mechanism may comprise a flow path connected to a source of the gas.

The gas supply mechanism may comprise a container of the gas and an electronic valve controlled by a controller for supplying the gas to the light-emitting heating elements, or for stopping the supply of the gas.

Alternatively, the gas supply mechanism may comprise two or more containers of gasses and respective valves, wherein gasses from more than one of the containers are mixed to produce the gas. For example, one of the containers may contain nitrogen and another of the containers may contain oxygen or an oxygen containing gas such as air, and these gases may be mixed together to produce the gas supplied to the array of light-emitting elements. Alternatively, a multi-way valve may be used instead of multiple valves.

According to a fourth aspect of the present invention there is provided a method of at least partially restoring the output of light-emitting heating elements, in an apparatus comprising:
a support configured to support a wafer-shaped article;
a heating assembly comprising an array of light-emitting heating elements configured to heat a wafer-shaped article supported by the support; and
a gas supply mechanism configured to supply to the array of light-emitting heating elements:
   a first gas having an oxygen content of less than 1% by volume; and
   a second gas having an oxygen content that is at least 2% by volume higher than the first gas;
the method comprising:
using the gas supply mechanism to supply the second gas to the array of light-emitting heating elements.

The apparatus may have any of the features of the apparatus of the first to third aspects of the present invention discussed above. In particular, the support, heating assembly and gas supply mechanism may be the same as the support, heating assembly or gas supply mechanism of any of the other aspects of the present invention discussed above.

The method may comprise supplying the second gas to degraded light-emitting heating elements while not processing a wafer-shaped article with the apparatus, similarly to the first and second aspect of the present invention discussed above. This method may have any of the features of the first and second aspects of the present invention discussed above.

Typically the method will also comprise providing power to the array of light emitting heating elements while providing the gas to the light-emitting heating elements.

The method may additionally comprise supplying the first gas to the array of light-emitting heating elements during processing of a wafer-shaped article.

According to a fifth aspect of the present invention there is provided a method of limiting degradation of light-emitting heating elements in an apparatus for processing wafer-shaped articles, the apparatus comprising:
a support configured to support a wafer-shaped article;
a heating assembly comprising an array of light-emitting heating elements configured to heat a wafer-shaped article supported by the support; and a gas supply mechanism for supplying a gas to the array of light-emitting heating elements;
the method comprising:
using the gas supply mechanism to supply a gas having an oxygen content of greater than 1% by volume to the array of light-emitting heating elements during processing of a wafer-shaped article by the apparatus.

The apparatus may have any of the features of the apparatus of the first to third aspects of the present invention discussed above. In particular, the support, heating assembly and gas supply mechanism may be the same as the support, heating assembly or gas supply mechanism of any of the other aspects of the present invention discussed above.

### BRIEF DESCRIPTION OF THE DRAWINGS

Embodiments of the present invention will now be discussed, by way of example only, with reference to the accompanying Figures, in which:

FIG. 1 is a schematic cross-sectional view of an apparatus according to an embodiment of the invention;

FIG. 2 is an example of a heating assembly that can be used in embodiments of the present invention;

FIG. 3 is a first example of a gas supply mechanism that can be used in embodiments of the present invention; and

FIG. 4 is a second example of a gas supply mechanism that can be used in embodiments of the present invention.

### DETAILED DESCRIPTION OF THE PREFERRED EMBODIMENTS AND FURTHER OPTIONAL FEATURES OF THE INVENTION

Aspects and embodiments of the present invention will now be discussed with reference to the accompanying figures. Further aspects and embodiments will be apparent to those skilled in the art. All documents mentioned in this text are incorporated herein by reference.

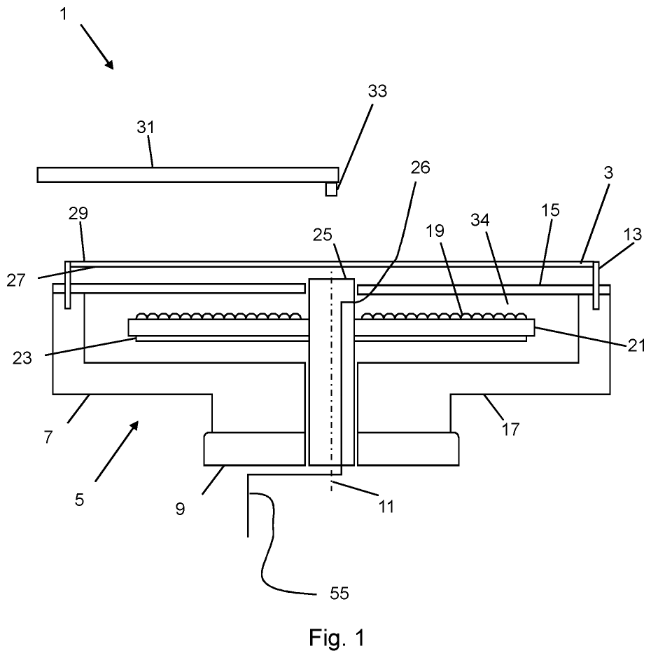

FIG. 1 shows a schematic cross-sectional view of an apparatus 1 for processing a wafer-shaped article according to a first embodiment of the present invention. In FIG. 1 a semiconductor wafer 3 is mounted in the apparatus 1 for processing.

The apparatus 1 includes a rotatable chuck 5 which is adapted to receive a wafer 3. The rotatable chuck 5 includes a chuck body 7 which is rotatably mounted on a base 9, for example via one or more bearings. The chuck body 7 is rotatable relative to the base 9 about an axis of rotation indicated by reference numeral 11. Rotation of the chuck body 7 relative to the base 9 may be driven, for example, by a motor (not shown), which may itself be controlled by a controller (not shown).

The chuck body 7 includes a set of gripping pins 13 which are adapted to receive the wafer 3 and to hold the wafer 3 securely in place. In this manner, when the wafer 3 is mounted on the rotatable chuck 5 via the gripping pins 13, the wafer 3 may be rotated by rotating the chuck body 7 relative to the base 9.

In the configuration shown in FIG. 1, the gripping pins 13 exert a gripping force to hold the wafer 3 in place. However, other suitable mechanisms may be used for holding the wafer 3 in place instead of the gripping pins 13 (e.g. clamp, screws, suction holder, etc.).

The rotatable chuck 5 further includes a plate 15 mounted on the chuck body 7. The plate 15 is secured to the chuck body 7, for example via one or more screws or bolts, such that it rotates with the chuck body 7 relative to the base 9. As shown in FIG. 1, the plate 15 is arranged such that it is substantially parallel to the wafer 3 when the wafer 3 is mounted in the rotatable chuck 5. In this embodiment the plate 15 is a transparent plate, for example made of quartz or sapphire.

The apparatus 1 further comprises a heating assembly 17. In this embodiment, the heating assembly 17 comprises an array of LEDs 19 arranged to illuminate a wafer 3 mounted in the rotatable chuck 5. The LEDs 19 serve as light-emitting heating elements for heating the wafer 3 received by the rotatable chuck 5.

In this embodiment, the heating assembly 17 is housed within a chamber, volume, or space formed inside the chuck body 7 and covered by the transparent plate 15.

In this embodiment, the LEDs 19 are arranged to emit light in a wavelength range from 380 nm to 650 nm. For example, the LEDs 19 may emit light having a maximum intensity in the wavelength range from 380 nm to 650 nm. Such a wavelength range is suitable for heating a semiconductor wafer.

The transparent plate 15 is configured such that it is substantially transparent to wavelengths emitted by the LEDs 19, i.e. all or a majority of light emitted by the LEDs 19 is transmitted by the transparent plate 15.

The heating assembly 17 further comprises a plate 21. The array of LEDs 19 is mounted on an upper surface of the plate 21, which acts as a heat-sink for the array of LEDs 19 to dissipate heat generated by the LEDs 19. For example, the plate 21 may be made of a metal such as aluminium. A circuit board 23 including driving circuitry (not shown) for the LEDs 19 is provided on a lower surface of the plate 21. Interconnections between the array of LEDs 19 and the driving circuitry on the circuit board are made through the plate 21.

The plate 21 is mounted on a stationary post 25, i.e. a post that does not rotate. The stationary post 25 is not connected to the chuck body 7, such that it does not rotate with the chuck body 7. The plate 21 is substantially parallel to the transparent plate 15.

The array of LEDs 19 is arranged to face towards the wafer 3 when the wafer is mounted in the rotatable chuck 5. As shown in FIG. 1, when the wafer 3 is mounted in the rotatable chuck 5, the transparent plate 15 is located between the array of LEDs 19 and the wafer 3. Thus, light emitted by the array of LEDs 19 may be transmitted by the transparent plate 15 and impinge on the wafer 3 to heat the wafer 3. The transparent plate 15 may serve to protect the array of LEDs 19 from processes that are performed on the wafer 3 when the wafer 3 is mounted in the rotatable chuck 5.

The array of LEDs 19 is arranged to illuminate a first surface 27 of the wafer 3, which is opposite a second surface 29 of the wafer 3. The second surface 29 of the wafer 3 is exposed, such that processes (e.g. etching, depositing of material, cleaning) may be performed on the second surface 29 of the wafer 3.

The array of LEDs 19 may be disposed substantially symmetrically about the axis of rotation 11 of the rotatable chuck 5. In this manner, the array of LEDs 19 may illuminate the wafer substantially symmetrically about the axis of rotation 11.

The apparatus 1 further comprises a liquid dispenser for dispensing a liquid on to the second surface 29 of the wafer 3, for example for cleaning the second surface 29. In this embodiment, the liquid dispenser includes an arm 31 having a discharge nozzle 33. The arm 31 is supplied with process and/or rinse liquid that is discharged downwardly through the discharge nozzle 33 onto the second surface 29 of the wafer 3.

The arm 31 is a swing arm 31 that is pivotally mounted at an end of the arm 31 opposite to an end of the arm 31 at which the discharge nozzle 33 is located, so that the arm 31 can be rotated about the pivotal mounting to change a position of the discharge nozzle 33 relative to the second surface 29 of the wafer 3. In particular, by rotating the arm 31 about the pivotal mounting, a radial position of the discharge nozzle 33 relative to the second surface 29 of the wafer 3 can be changed, for example between a first position located at a centre of the second surface 29 of the wafer 3 and a second position located radially outside an outer circumferential edge of the wafer 3. The discharge nozzle 33 is moved in an arc over the second surface 29 of the wafer 3.

The configuration of the liquid dispenser described above, together with the rotation of the wafer 3 by the rotatable chuck 5, means that the liquid dispenser can be operated to dispense liquid over the entire second surface 29 of the wafer 3, by pivoting the arm 31 from the centre of the second surface 29 to the edge of the second surface 29 while the wafer 3 is rotated.

Of course, in other embodiments other suitable liquid dispensers may be used instead of this specific liquid dispenser.

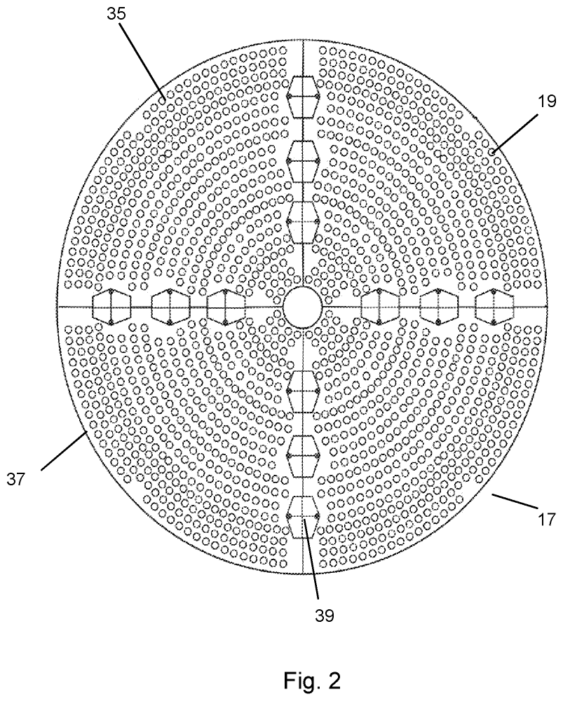

An example configuration of the heating assembly 17 in an embodiment of the present invention is illustrated in FIG. 2.

As shown in FIG. 2, the LEDs 19 are arranged on concentric rings around a centre of the heating assembly 17.

The arrangement of the LEDs 19 is rotationally symmetric around the centre of the heating assembly 17.

Within a given concentric ring, the LEDs 19 are bunched into groups 35, for example with 16 LEDs 19 in each group 35. In other words, the LEDs 19 in a given concentric ring are not evenly distributed around the concentric ring. The power to each of the groups 35 of LEDs 19 may be independently controlled.

In this example there are 20 concentric rings of LEDs 19, but of course in other embodiments the number of concentric rings may be different.

In FIG. 2, the heating assembly 17 is divided into four quadrants 37, which are joined together by connectors 39.

Each LED may have a power consumption of 10 W and provide a power of 3 W.

Of course, the heating assembly 17 may be different to that illustrated in FIG. 2. In particular, the arrangement of the LEDs in the heating assembly 17 is not essential to the present invention.

The apparatus 1 of the present invention may be used to clean the second surface 29 of the wafer 3 by applying a cleaning liquid such as isopropyl alcohol to the second surface 29 of the wafer 3 using the liquid dispenser. The second surface 29 of the wafer 3 may then be dried by spinning the wafer 3 with the chuck body 7 and heating the wafer 3 with the LEDs 19 to cause evaporation of the cleaning liquid or rinse liquid. Such a cleaning process is commonly referred to as a spin-clean process.

During processing of the wafer 3 by the apparatus 1, one or more flammable liquids may be dispensed on the second surface 29 of the wafer 3 by the discharge nozzle 33. For example, in spin-cleaning of the wafer 3 flammable isopropyl alcohol may be dispensed on the second surface 29 of the wafer 3.

As mentioned above, the transparent plate 15 is provided between the wafer 3 and the heating assembly 17 to protect the heating assembly 17 from coming into contact with such processing liquids. However, there is still a possibility that some of the processing liquid may infiltrate inside the chuck body 7, for example by infiltrating along a contact area between the transparent plate 15 and the chuck body 7, or through one or more mounting holes formed in the transparent plate 15. Therefore, there is still a possibility that some of the processing liquid could come into contact with the heating assembly 17 located inside the chuck body 7.

As mentioned above, the heating assembly 17 includes a circuit board 23 including driving circuitry for the LEDs 19 provided on a lower surface of the plate 21. If flammable processing liquids come into contact with the circuit board 23, there is a potential risk of fire or explosion of the flammable liquid.

In order to remove or significantly reduce this risk, it is known to provide an inert atmosphere around the heating assembly 17, so that there is no risk, or significantly reduced risk, of fire or explosion if flammable processing liquids come into contact with the circuit board 23.

In particular, it is known to provide a supply of pure nitrogen gas (N2) to the space surrounding the heating assembly 17, so that the LEDs 19 and the circuit board 23 are surrounded by pure nitrogen gas. The absence of oxygen in the atmosphere around the LEDs 19 and the circuit board 23 removes the risk of fire or explosion if flammable processing liquids come into contact with the circuit board 23.

In particular, the heating assembly 17 is substantially enclosed in a chamber 34 formed by an internal surface of the chuck body 7 and the bottom surface of the transparent plate 15. Pure nitrogen gas can be supplied to the chamber 34 so that there is an inert atmosphere in the chamber 34 surrounding the heating assembly 17.

For example, a gas supply passage may be provided in the stationary post 25 that has outlets in the chamber 34, so that nitrogen gas can be supplied through the stationary post 25 to the chamber 34. However, a gas supply passage may instead be provided in a different location.

One or more gas outlets from the chamber 34 to outside of the chamber 34 may be provided, so that there is a flow of gas into the chamber and out of the one or more gas outlets.

The present inventors have discovered that operating the LEDs 19 in such an inert atmosphere surprisingly causes a drop in the light output of the LEDs 19 over time. For example, the light output of the LEDs 19 has been observed to fall to as low as 30% of the original value after prolonged operation of the LEDs 19 in the inert atmosphere. A drop in the light output of the LEDs causes a corresponding drop in the heating of the wafer 3, and therefore a corresponding drop in the effectiveness of the drying of the wafer 3. In contrast, the present inventors have observed that operating the LEDs 19 in a normal atmosphere (for example air) causes a drop of less than 10% of the light output of the LEDs 19 over the whole lifetime of the LEDs 19 (a much longer period of time).

A change in colour of the LEDs 19 that accompanies the drop in the light output of the LEDs 19 during operation of the LEDs 19 in the inert atmosphere has also been observed by the present inventors.

The present inventors have further discovered that this degradation in the light output of the LEDs 19 can be at least partially reversed by operating the degraded LEDs 19 in a normal atmosphere (for example air) for a period of time. In particular, the present inventors have found that by operating the degraded LEDs 19 in a normal atmosphere (for example air) for a period of time, the light output of the LEDs can be returned to close to the original value, for example within 1% of the original value.

Therefore, the apparatus 1 according to the present invention includes a gas supply mechanism that is arranged to supply both an inert gas (a gas with no oxygen or a low level of oxygen) to the chamber 34 and a non-inert gas (an oxygen containing gas) to the chamber 34.

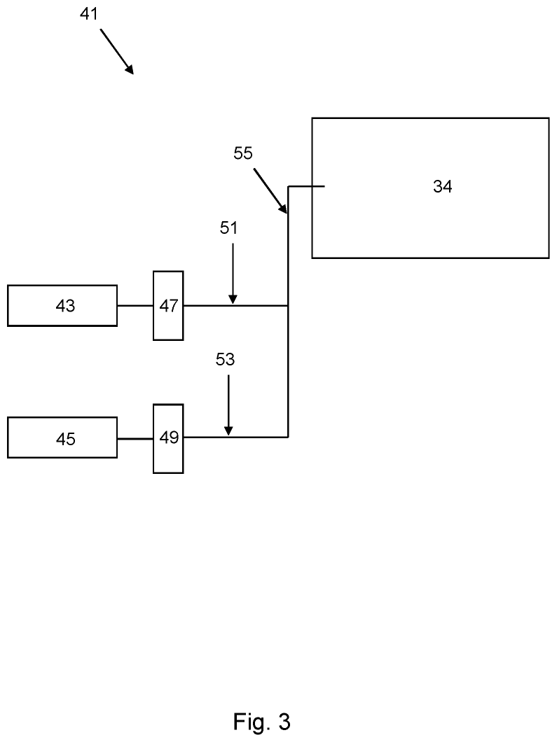

An example of the gas supply mechanism in the present invention is illustrated in FIG. 3. As shown in FIG. 3, the gas supply mechanism 41 includes a first container 43 containing a first gas and a second container 45 containing a second gas.

The first gas in the first container 43 is an inert gas (a gas with no oxygen or a low level of oxygen). In this embodiment, the first gas is pure nitrogen. However, in other embodiments a different inert gas may be used instead of nitrogen.

The second gas in the second container 45 is a gas that includes more oxygen than the first gas (a non-inert gas). In this embodiment, the second gas is extra clean dry air (XCDA). However, in other embodiments a different oxygen containing gas may be used instead of air or XCDA.

The gas supply mechanism further comprises a first valve 47 connected to the first container 43 and a second valve 49 connected to the second container 43.

The first and second valves 47 and 49 are electronic valves that can be controlled by a controller to open to allow flow of the first or second gas respectively, and to close to block flow of the first or second gas respectively.

The gas supply mechanism 41 further comprises a first gas flow path 51 passing from the first container 43 through the first valve 47 to an inside of the chamber 34, and a second flow path 53 passing from the second container 45 through the second valve 49 to the inside of the chamber 34.

In this embodiment, the first and second gas flow paths 47 and 53 are combined in a single gas flow path 55 before entering the inside of the chamber 34. However, in alternative embodiments the first and second gas flow paths 47 and 53 may be entirely separate.

The gas flow path(s) may communicate with the chamber 34 via the stationary post 25. Specifically, the stationary post 25 may include a passageway (or respective passageways) that forms part of the first and second gas flow paths 47, 53 and that has one or more outlets into the chamber 34, for example via one or more outlet holes formed in the side surface of the stationary post 25. Therefore, the first and second gasses can be provided to the chamber 34 via the stationary post 25.

Therefore, the first and second gasses can be discharged into the chamber 34 by the first and second gasses being provided through the passageway (or respective passageways) formed in the stationary post 25 and discharged into the chamber 34 through one or more outlet holes or nozzles 26 formed in the side surface of the stationary post 25.

In one embodiment, a passageway is provided in the stationary post 25 that connects an inlet on a bottom end surface of the stationary post 25 with an outlet (nozzle 26) on a side surface of the stationary post 25 located in the chamber 34. Therefore, the first or second gas can be provided to the chamber 34 by inputting the first or second gas into the inlet of the passageway, so that it is discharged into the chamber 34 via the nozzle 26.

One or more gas outlets are provided to allow gas to escape from the chamber 34. Therefore, when the first or second gas is supplied to the chamber 34 there is a continuous flow of the first or second gas into the chamber and out of the gas outlet(s). For example, the gas outlet(s) may comprise one or more through holes formed in a wall of the chuck body 7, or in a periphery of the transparent plate 15.

This means that when the gas is switched from the first gas to the second gas or visa-versa, the initial gas is flushed out of the chamber 34 by the subsequent gas.

The gas supply mechanism 41 of the present invention is therefore operable to supply either the first gas to the chamber 34 to provide an atmosphere comprising the first gas in the chamber 34 surrounding the heating assembly 17, or to provide the second gas to the chamber 34 to provide an atmosphere comprising the second gas in the chamber 34 surrounding the heating assembly. The LEDs 19 can therefore be operated in either an atmosphere comprising the first gas (pure nitrogen in this embodiment) or an atmosphere comprising the second gas (extra clean dry air in this embodiment).

An operation of the apparatus 1 in an embodiment of the present invention will now be described.

As illustrated in FIG. 1, when a wafer 3 is to be processed by the apparatus 1, the wafer 3 is mounted on the rotatable chuck 5 via the gripping pins 13. In particular, the gripping pins 13 contact the wafer 3 and restrain lateral movement of the wafer 3. For example, the gripping pins 13 may be movable to contact an outer periphery of the wafer 3 on opposite sides of the outer periphery of the wafer 3, so that the wafer 3 is held in position by the gripping pins 13. Of course, in other embodiments a different mechanism for mounting the wafer on the rotatable chuck 5 may be provided instead of the gripping pins 13.

Once the wafer 3 is mounted on the rotatable chuck 5, the rotatable chuck 5 is rotated so as to rotate the wafer 3, using a motor coupled to the rotatable chuck 5.

While the wafer 3 is rotated by the rotatable chuck 5, a processing liquid such as isopropyl alcohol is dispensed onto the upper surface 29 of the wafer 4 using the discharge nozzle 33. The discharge nozzle 33 is moved in an arc across the second surface 29 of the wafer 3 while the wafer 3 is rotated, so that the isopropyl alcohol is dispensed over the whole surface of the wafer 3.

The gas supply mechanism 41 is controlled by a controller of the apparatus 1 so that the first valve 47 is opened and the second valve 45 is closed. This means that pure nitrogen gas in the first container 43 is supplied to the chamber 34 around the heating assembly 17. The chamber 34 around the heating assembly 17 is therefore filled with pure nitrogen, which is an inert gas. The atmosphere around the heating assembly 17 is therefore an inert atmosphere.

The controller of the apparatus supplies power to the heating assembly 17, so that power is supplied to the LEDs 19. As discussed above, different amounts of power may be supplied to different ones of the LEDs or to different groups of the LEDs 19 so that the LEDs 19 or groups of LEDs provide different amounts of light. Alternatively, the same amount of power may be provided to all of the LEDs 19 so that all of the LEDs 19 produce the same amount of light.

The LEDs 19 therefore emit light that passes through the transparent plate 15 and is incident on the first surface 27 of the wafer 3. The light is absorbed by the first surface 27 of the wafer 3 such that the wafer 3 is heated. Heating of the wafer 3 causes evaporation of the processing liquid on the second surface 29 of the wafer 3.

The transparent plate 15 is positioned between the heating assembly 17 and the wafer 3, and protects the heating assembly 17 from the processing liquid. However, there is a risk that some of the processing liquid may still infiltrate past the transparent plate 15 into the chamber 34, where it may come into contact with the heating assembly 17.

As discussed above, the heating assembly 17 includes a circuit board 23 including driving circuitry for the LEDs 19.

If flammable processing liquid came into contact with the circuit board 23 in a normal atmosphere, there would be a risk of fire or explosion of the flammable liquid. However, in the present invention the inert atmosphere in the chamber 34 prevents, or significantly reduces the risk of, such fire or explosion.

As mentioned above, the present inventors have discovered that prolonged operation of the LEDs 19 in an inert atmosphere in the chamber 34 causes degradation in the light output of the LEDs. For example, the light output of the LEDs has been found to fall to as low as 30% of the original light output of the LEDs after prolonged operation in an inert atmosphere.

As discussed above, the present inventors have further discovered that surprisingly this degradation in the light output of the LEDs 19 can be at least partially reversed by operating the degraded LEDs 19 in a normal atmosphere (for example air) for a period of time. In particular, the present inventors have found that by operating the degraded LEDs 19 in a normal atmosphere (for example air) for a period of time, the light output of the LEDs can be returned to close to the original value, for example within 1% of the original value.

Therefore, in the present invention, the apparatus 1 periodically performs an LED repair procedure to restore the light output of the LEDs 19, as discussed below.

The LED repair procedure may be performed after a predetermined duration of operating the LEDs 19 in the inert atmosphere, or after a predetermined number of wafers 3 have been processed by the apparatus 1, or when it is detected that the light output of one or more of the LEDs 19 has decreased by a predetermined amount or to a predetermined level (detected using a light sensor or a camera, for example). Alternatively, the LED repair procedure may instead be performed at a set time interval or following a predetermined schedule, or after each time a wafer 3 is processed by the apparatus 1.

The LED repair procedure is only performed when no flammable liquid is being dispensed from the discharge nozzle 33, in order to reduce the risk of fire or explosion.

The LED repair procedure is generally performed without a wafer 3 being received on the rotatable chuck 5.

In the LED repair procedure, the gas supply mechanism 41 is controlled so that the first valve 47 is closed and the second valve 49 is opened. This means that only the second gas is supplied to the chamber 34. The chamber 34 around the heating assembly 17 is therefore filled with the second gas.

In this embodiment, the second gas is extra clean dry air. The atmosphere in the chamber 34 during the LED repair procedure is therefore air (a normal atmosphere), which is not an inert gas.

While the chamber 34 is filled with the extra clean dry air, the controller supplies power to the LEDs 19. For example, all of the LEDs 19 may be supplied with the same amount of power. Alternatively, different LEDs 19 or groups of LEDs 19 may be provided with different amounts of power. The power supplied to the LEDs 19 may be a lower amount than the power supplied to the LEDs 19 during the processing operation of the wafer 3.

Power is supplied to the LEDs 19 in the atmosphere of extra clean dry air for a predetermined period of time. For example, power may be supplied to the LEDs in the atmosphere of extra clean dry air for a period of one hour, in one example. However, in some cases power may only need to be supplied to the LEDs in the atmosphere of extra clean dry air for a period of a few second or minutes. The length of time for which the power is supplied to the LEDs is generally predetermined in advance.

The present inventors have discovered that surprisingly this LED repair procedure partly or substantially repairs the degradation in the light output of the LEDs 19, so that the light output of the LEDs 19 increases closer to the original value (is at least partially restored). For example, it may be possible to restore the outputs of the LEDs 19 to within 1% of the original light output of the LEDs 19.

Providing power to the LEDs 19 is advantageous because it significantly reduces the length of time required for recovery of the light output of the LEDs 19. However, in an alternative embodiment the second gas may be provided to the LEDs 19 in the LED recovery procedure without supplying power to the LEDs, and this procedure may be carried out for a significantly longer period of time.

In this embodiment, the first gas is nitrogen. However, it is not necessary for the first gas to be nitrogen. Instead, it is only necessary for the first gas to have a sufficiently low oxygen content to be substantially inert so as to reduce the risk of flammable processing liquids from catching fire or exploding. In general, an oxygen content of less than 1% by volume is sufficient to make the first gas sufficiently inert. Therefore, the first gas may alternatively be any gas having an oxygen content of less than 1% by volume. In general, the oxygen content of the first gas is insufficient for combustion.

In this embodiment the heating elements are LEDs 19. However, similar degradation is expected to occur with other types of light-emitting heating elements. Therefore, the LEDs 19 may instead be other types of light-emitting heating elements.

In this embodiment the second gas is extra clean dry air. Of course, normal air may be used instead of extra clean dry air. More generally, any gas containing a suitable amount of oxygen can be used as the second gas. For example, an oxygen content of more than 1% by volume may be sufficient to repair the degradation of the LEDs 19. Preferably, the second gas has an oxygen content of more than 2% by volume, or more than 3% by volume, or more than 4% by volume, or more than 5% by volume. The second gas may have an oxygen content of more than 10% by volume, or more than 15% by volume.

In other embodiments, the chuck 5 may not be rotatable.

In other embodiments, the structure and/or appearance of the chuck 5 may be different to that illustrated in FIG. 1.

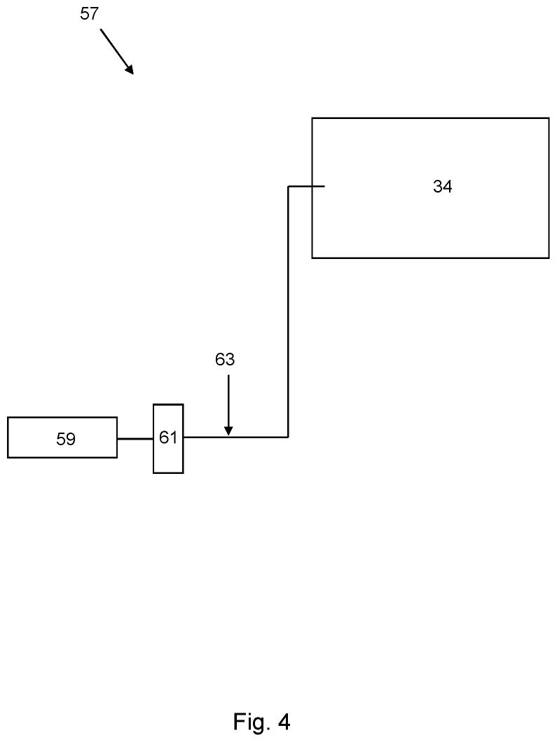

A gas supply mechanism 57 according to a second embodiment of the present invention is illustrated in FIG. 4. In this embodiment, the gas supply mechanism 57 includes only a single container 59 and valve 61. A gas flow path 63 is provided from the container 59 to the inside of the chamber 34 via the valve 61.

In this embodiment, the container 59 contains a gas with an oxygen content that is sufficiently high to prevent significant degradation of the LEDs 19 during operation of the LEDs 19 in an atmosphere of the gas, but that is sufficiently low to reduce a risk of fire or explosion of flammable processing liquids. For example, the gas may have an oxygen content between 1% and 10% by volume, or between 2% and 10% by volume, or between 3% and 10% by volume, or between 1% and 5% by volume, or between 2% and 5% by volume, or between 3% and 5% by volume.

In this embodiment, there is no LED repair procedure. Instead, during operation of the apparatus 1 to process a wafer 3, the valve 61 is opened so that the gas from the container 59 is supplied to the chamber 34, and the LEDs 19 are then operated to heat the wafer 3 in an atmosphere of the gas. The oxygen content of the gas is sufficient that significant degradation of the LEDs 19 does not occur, and therefore no separate LED repair procedure is required.

In a further embodiment, two gas containers 43, 45 and valves 47, 49 may be provided as in FIG. 3. However, the two gases in the two containers 43, 45 may be mixed together in the flow passage to provide a single gas to the chamber 34, wherein the single gas has the same composition as the single gas discussed above. This can be achieved by simultaneously opening or partially opening both of the valves 47 and 49 to produce a mixture of the two gasses in the flow path 55. For example, one of the containers 43, 45 may contain an inert gas such as nitrogen, and the other container 43, 45 may contain oxygen or an oxygen containing gas.

The features disclosed in the foregoing description, or in the following claims, or in the accompanying drawings, expressed in their specific forms or in terms of a means for performing the disclosed function, or a method or process for obtaining the disclosed results, as appropriate, may, separately, or in any combination of such features, be utilised for realising the invention in diverse forms thereof.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

For the avoidance of any doubt, any theoretical explanations provided herein are provided for the purposes of improving the understanding of a reader. The inventors do not wish to be bound by any of these theoretical explanations.

Any section headings used herein are for organizational purposes only and are not to be construed as limiting the subject matter described.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

It must be noted that, as used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by the use of the antecedent “about,” it will be understood that the particular value forms another embodiment. The term “about” in relation to a numerical value is optional and means for example +/−10%.

1. An apparatus for processing wafer-shaped articles, the apparatus comprising:
a support configured to support a wafer-shaped article;
a heating assembly comprising an array of light-emitting heating elements configured to heat a wafer-shaped article supported by the support; and
a gas supply mechanism configured to supply to the array of light-emitting heating elements:
a first gas having an oxygen content of less than 1% by volume; and
a second gas having an oxygen content that is at least 2% by volume higher than the first gas.

2. The apparatus according to claim 1, wherein the second gas has an oxygen content that is at least 5% by volume higher than the first gas.

3. The apparatus according to claim 1, wherein the first gas has an oxygen content of less than 0.5% by volume, or less than 0.1% by volume.

4. The apparatus according to claim 1, wherein the first gas is an inert gas.

5. The apparatus according to claim 1, wherein the first gas comprises nitrogen.

6. The apparatus according to claim 1, wherein the second gas comprises air.

7. The apparatus according to claim 1, wherein the apparatus is configured to supply the first gas to the array of light-emitting heating elements during processing of a wafer-shaped article by the apparatus.

8. The apparatus according to claim 1, wherein the apparatus is configured to only supply the second gas to the array of light-emitting heating elements when a wafer-shaped article is not being processed by the apparatus.

9. The apparatus according to claim 1, wherein the light-emitting heating elements are LEDs.

10. The apparatus according to claim 1, wherein the apparatus comprises a liquid dispenser for dispensing a liquid on to a surface of the wafer-shaped article.

11. The apparatus according to claim 10, wherein the apparatus is configured to only supply the second gas to the array of light-emitting heating elements when the liquid is not being dispensed on to the surface of the wafer-shaped article.

12. The apparatus according to claim 10, wherein the array of light-emitting heating elements is arranged to heat a surface of the wafer that is on an opposite side of the wafer compared to the surface of the wafer on which the liquid is dispensed.

13. The apparatus according to claim 1, wherein the apparatus is configured to provide power to the array of light-emitting heating elements while the second gas is being supplied to the array of light-emitting heating elements.

14. The apparatus according to claim 1, wherein the apparatus is configured to only provide the second gas to the array of light-emitting heating elements when no wafer-shaped article is supported by the support.

15. The apparatus according to claim 1, wherein the apparatus is configured to:
supply the second gas to the array of light-emitting heating elements after a predetermined period of time of processing of wafer-shaped articles by the apparatus has elapsed; and/or
supply the second gas to the array of light-emitting heating elements after a predetermined number of wafer-shaped articles have been processed by the apparatus; and/or
supply the second gas to the array of light-emitting heating elements when an output of one or more of the light-emitting heating elements has dropped by a predetermined amount, or is a predetermined value; and/or
supply the second gas to the array of light-emitting heating elements based on a predetermined schedule.

16. The apparatus according to claim 1, wherein the gas supply mechanism comprises:
a first gas path connected to a source of the first gas; and
a second gas path connected to a source of the second gas.

17. The apparatus according to claim 1, wherein the gas supply mechanism comprises one or more valves configured to control the supply of the first gas and/or the supply of the second gas to the array of light-emitting heating elements.

18. The apparatus according to claim 1, wherein the gas supply mechanism comprises:
a first valve for connecting to a source of the first gas, and a gas flow path for transporting the first gas from the first valve to the array of light-emitting heating elements; and a second valve for connecting to a source of the second gas, and a gas flow path for transporting the second gas from the second valve to the array of light-emitting heating elements; or
a multi-way valve connected to a source of the first gas and a source of the second gas, and a gas flow path for transporting the first gas and the second gas from the multi-way valve to the array of light-emitting heating elements; or
a first gas path connected to a source of the first gas, a second gas path connected to a source of the second gas, and a valve in the second gas path.

19. An apparatus for processing wafer-shaped articles, the apparatus comprising:
a support configured to support a wafer-shaped article;
a heating assembly comprising an array of light-emitting heating elements configured to heat a wafer-shaped article supported by the support; and
a gas supply mechanism configured to supply gas to the array of light-emitting heating elements, wherein the gas supply mechanism comprises:
a first gas path connected to a source of a first gas;
a second gas path connected to a source of a second gas; and
one or more valves configured to control the supply of the first gas and/or the supply of the second gas to the array of light-emitting heating elements.

20. An apparatus for processing wafer-shaped articles, the apparatus comprising:
a support configured to support a wafer-shaped article;
a heating assembly comprising an array of light-emitting heating elements configured to heat a wafer-shaped article supported by the support; and
a gas supply mechanism configured to supply to the array of light-emitting heating elements a gas having an oxygen content of greater than 1% by volume during processing of a wafer-shaped article by the apparatus.

21. A method of at least partially restoring the output of light-emitting heating elements in an apparatus for processing wafer-shaped articles, the apparatus comprising:
a support configured to support a wafer-shaped article;
a heating assembly comprising an array of light-emitting heating elements configured to heat a wafer-shaped article supported by the support; and
a gas supply mechanism configured to supply to the array of light-emitting heating elements:
a first gas having an oxygen content of less than 1% by volume; and
a second gas having an oxygen content that is at least 2% by volume higher than the first gas;
the method comprising:
using the gas supply mechanism to supply the second gas to the array of light-emitting heating elements.

22. A method of limiting degradation of light-emitting heating elements in an apparatus for processing wafer-shaped articles, the apparatus comprising:
a support configured to support a wafer-shaped article;
a heating assembly comprising an array of light-emitting heating elements configured to heat a wafer-shaped article supported by the support; and
a gas supply mechanism for supplying a gas to the array of light-emitting heating elements;
the method comprising:
using the gas supply mechanism to supply a gas having an oxygen content of greater than 1% by volume to the array of light-emitting heating elements during processing of a wafer-shaped article by the apparatus.
